(19) United States
(12) Patent Application Publication
(10) Pub. No.: US 2023/0038597 A1
(43) Pub. Date: Feb. 9, 2023

(54) PLASMA PROCESSING DEVICE AND METHOD FOR MANUFACTURING DISPLAY DEVICE BY USING THE SAME

(71) Applicant: Samsung Display Co., LTD., Yongin-si (KR)

(72) Inventors: Soo Youn KIM, Siheung-si (KR); Hee Jun YANG, Hwaseong-si (KR); Seung Ho YOON, Hwaseong-si (KR); Se Hoon JEONG, Suwon-si (KR)

(21) Appl. No.: 17/880,588

(22) Filed: Aug. 3, 2022

(30) Foreign Application Priority Data
Aug. 4, 2021 (KR) 10-2021-0102609

(51) Int. Cl. H01J 37/32; H01L 21/3065; H01L 21/56

(52) U.S. Cl. CPC H01J 37/32009; H01J 37/3244; H01J 37/32532; H01L 21/3065; H01L 21/56

(57) ABSTRACT

A method for manufacturing a display device according to an embodiment includes: forming a display panel including a first substrate, a second substrate facing the first substrate, an emission layer disposed between the first substrate and the second substrate, a pad portion disposed on the first substrate, and a thin film encapsulation layer disposed on the pad portion; removing the thin film encapsulation layer disposed on the pad portion by using a plasma processing device; and attaching a flexible circuit board on which an integrated circuit chip is mounted to the pad portion exposed by removing the thin film encapsulation layer.

This application claims priority to Korean Patent Application No. 10-2021-0102609, filed on Aug. 4, 2021, and all the benefits accruing therefrom under 35 U.S.C. § 119, the content of which in its entirety is herein incorporated by reference.

### BACKGROUND OF THE INVENTION

### (a) Field of the Invention

The present disclosure relates to a plasma processing device and a display device manufacturing method using the same.

### (b) Description of the Related Art

A flat panel display includes a liquid crystal display (“LCD”), a plasma display panel (“PDP”), an organic light emitting diode (“OLED”) device, a field effect display (“FED”), and an electrophoretic display device.

The display device includes a display area including a plurality of pixels for displaying images and a peripheral area disposed near the display area, and the display device further includes a driver disposed in the peripheral area and for transmitting signals to a plurality of signal lines included in the pixels.

To connect the signal lines and the driver of the display device, a plasma processing device is used to etch an insulating layer disposed on the signal lines and eliminate them.

When a step that is a difference of surface heights between the display area and the peripheral area, insufficient plasma gas may be applied to the insulating layer positioned near the display area and the peripheral area, and the insulating layer may not be completely removed. By this, the signal lines may not be connected to the driver.

### SUMMARY OF THE INVENTION

The present invention has been made in an effort to provide a plasma processing device for removing an insulating layer positioned on an adjacent portion of a display area and a peripheral area when there is a surface step between a display area and a peripheral area provided around the display area, and a display device manufacturing method using the same.

The aspect of the present invention is not limited to the above-described aspect, and it may be expanded in various ways in the range of the ideas and the areas of the present invention.

An embodiment of the present invention provides a plasma processing device including: a power supply unit; a plasma electrode connected to the power supply unit; a plasma processor in which the plasma electrode is installed; a process gas discharging duct connected to the plasma processor; and a gas direction changer disposed between the plasma processor and the process gas discharging duct.

The gas direction changer may include a groove portion defined on an inner side thereof.

The groove portion may have a spiral shape on the inner side of the gas direction changer.

The groove portion may have a predetermined angle with respect to the inner side of the gas direction changer.

The predetermined angle may be about 30 degrees to about 60 degrees.

A depth of the groove may be about 1 millimeter (mm) to about 2 mm.

The spiral shape of the groove may be disposed at an equal interval, the predetermined angle may be about 45 degrees, and the equal interval may be about 10 mm.

The gas direction changer may include a nozzle and a gas direction changing filter disposed to traverse an inside of the nozzle.

The gas direction changing filter may define a plurality of holes therein.

Process gas may be discharged as a linear flow when passing through the plasma processor, and the process gas may be discharged as a turbulent flow when passing through the gas direction changer.

Another embodiment of the present invention provides a method for manufacturing a display device including: forming a display panel including a first substrate, a second substrate facing the first substrate, an emission layer disposed between the first substrate and the second substrate, a pad portion disposed on the first substrate, and a thin film encapsulation layer disposed on the pad portion; removing the thin film encapsulation layer disposed on the pad portion by using a plasma processing device; and attaching a flexible circuit board on which an integrated circuit chip is mounted to the pad portion exposed by removing the thin film encapsulation layer.

The display device may further include a color converting panel disposed between the emission layer and the second substrate, the display panel may include a display area including the emission layer and the color converting panel, a driver area in which the pad portion is disposed, and a blocking area disposed between the display area and the driver area, the thin film encapsulation layer may include a first inorganic encapsulation layer, a second inorganic encapsulation layer, and an organic encapsulation layer disposed between the second inorganic encapsulation layer and the second inorganic encapsulation layer, the organic encapsulation layer may be disposed in the display area, the first inorganic encapsulation layer and the second inorganic encapsulation layer may be disposed in the display area and the blocking area, and the removing of the thin film encapsulation layer may include removing the first inorganic encapsulation layer and the second inorganic encapsulation layer disposed in the driver area.

The removing of the thin film encapsulation layer may include using process gas discharged as a turbulent flow from the plasma processing device.

The plasma processing device may include a power supply unit, a plasma electrode connected to the power supply unit, a plasma processor in which the plasma electrode is installed, a process gas discharging duct connected to the plasma processor, and a gas direction changer disposed between the plasma processor and the process gas discharging duct, and the removing of the thin film encapsulation layer may include using the process gas passing through the gas direction changer.

The gas direction changer may include a groove portion defined on an inside thereof, the groove portion may have a spiral shape on the inside of the gas direction changer, and the removing of the thin film encapsulation layer may include using the process gas passing through the groove portion of the spiral shape.

The gas direction changer may include a nozzle and a gas direction changing filter disposed to traverse an inside of the nozzle, and the removing of the thin film encapsulation layer may include using the process gas passing through the gas direction changing filter.

The gas direction changing filter may define a plurality of holes therein, and the removing of the thin film encapsulation layer may include using the process gas passing through the holes.

A flux of the process gas supplied to a region that is near the display area from among the driver area may be substantially equivalent to a flux of the process gas supplied to another region of the driver area.

An etch rate of removing of the thin film encapsulation layer spaced apart from the blocking area by about 100 micrometers (μm) from among the driver area may be substantially equivalent to the etch rate of removing of the thin film encapsulation layer spaced apart from the blocking area by equal to or greater than about 500 μm from among the driver area.

According to the embodiments, when there is a surface step between the display area and the peripheral area disposed around the display area, the insulating layer positioned on the adjacent portion of the display area and the peripheral area may be sufficiently removed.

The aspect of the present embodiment is not limited to the above-described aspect, and it may be expanded in various ways in the range of the ideas and the areas of the present invention.

### BRIEF DESCRIPTION OF THE DRAWINGS

FIG. 1 shows a top plan view of a display device according to an embodiment.

FIG. 2 shows a cross-sectional view of a display device according to an embodiment.

FIG. 3 to FIG. 5 show cross-sectional views of a method for manufacturing a display device according to an embodiment.

FIG. 6 shows a schematic diagram of a plasma processing device according to an embodiment.

FIG. 7 shows a cross-sectional view of a gas direction changer of a plasma processing device according to an embodiment.

FIG. 8 shows a cross-sectional view of a gas direction changer of a plasma processing device according to an embodiment.

FIG. 9 shows a top plan view of a gas direction changing filter of a plasma processing device according to an embodiment.

FIG. 10 and FIG. 11 show graphs of a supplying direction and a supplied amount of gas supplied to a step portion.

FIG. 12 and FIG. 13 show graphs of etch rates with respect to position.

### DETAILED DESCRIPTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

Parts that are irrelevant to the description will be omitted to clearly describe the present invention, and the same elements will be designated by the same reference numerals throughout the specification.

The accompanying drawings are provided only in order to allow embodiments disclosed in the present specification to be easily understood and are not to be interpreted as limiting the spirit disclosed in the present specification, and it is to be understood that the present invention includes all modifications, equivalents, and substitutions without departing from the scope and spirit of the present invention.

The size and thickness of each configuration shown in the drawings are arbitrarily shown for better understanding and ease of description, but the present invention is not limited thereto. The thicknesses of layers, films, panels, regions, etc., are enlarged for clarity. The thicknesses of some layers and areas are exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

Unless explicitly described to the contrary, the word “comprise” and variations such as “comprises” or “comprising” will be understood to imply the inclusion of stated elements but not the exclusion of any other elements.

The phrase “in a plan view” means viewing an object portion from the top, and the phrase “in a cross-sectional view” means viewing a cross-section of which the object portion is vertically cut from the side.

When it is described that a part is “connected” to another part, the part may be “directly connected” to the other element, may be “connected” to the other part through a third part, or may be connected to the other part physically or electrically, and they may be referred to by different titles depending on positions or functions, but respective portions that are substantially integrated into one body may be connected to each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Various embodiment and variations will now be described in detail with reference to accompanying drawings.

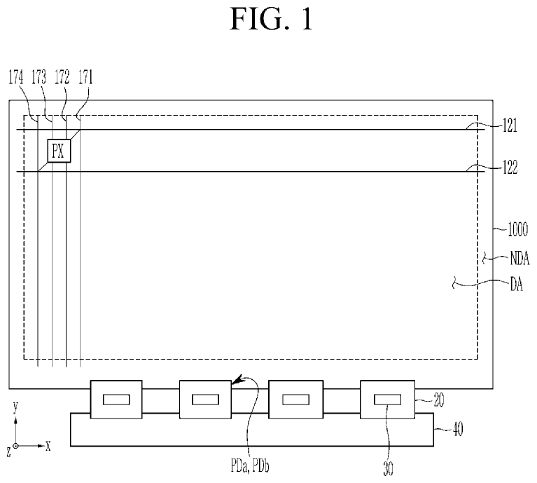

A display device according to an embodiment will now be described with reference to FIG. 1. FIG. 1 shows a top plan view of a display device according to an embodiment.

Referring to FIG. 1, the display device may include a display panel 1000, a flexible circuit board 20, an integrated circuit chip 30, and a printed circuit board (“PCB”) 40.

The display panel 1000 includes a display area DA that corresponds to a screen for displaying images, and a non-display area NDA in which circuits and/or signal lines for generating and/or transmitting various signals applied to the display area DA are disposed. The non-display area NDA may surround the display area DA. In FIG. 1, a boundary of the display area DA and the non-display area NDA is indicated with a dotted quadrangle.

A plurality of pixels PX may be disposed in a matrix in the display area DA of the display panel 1000. The signal lines such as a first scan line 121, a second scan line 122, a data line 171, a driving voltage line 172, a common voltage line 173, and an initializing voltage line 174 may be disposed in the display area DA.

The first scan line 121 and the second scan line 122 may substantially extend in a first direction X. The data line 171, the driving voltage line 172, the common voltage line 173, and the initializing voltage line 174 may substantially extend in a second direction Y.

At least one of the driving voltage line 172, the common voltage line 173, and the initializing voltage line 174 may include a voltage line substantially extending in the first direction X and a voltage line substantially extending in the second direction Y, and may be disposed in a mesh form.

Each pixel PX may be connected to the first scan line 121, the second scan line 122, the data line 171, the driving voltage line 172, the common voltage line 173, and the initializing voltage line 174, and may receive a first scan signal, a second scan signal, a data voltage, a common voltage, and a driving voltage from the signal lines. Each pixel PX may include a light emitting element such as a light emitting diode LED.

Touch electrodes (not shown) for sensing contact and/or non-contact touches of a user may be disposed in the display area DA of the display panel 1000.

A first pad portion PDa on which pads for receiving signals from an outside of the display panel 1000 may be disposed in the non-display area NDA of the display panel 1000, and a first end portion of the flexible circuit board 20 may be bonded to the display panel 1000 through the first pad portion PDa.

A second pad portion PDb on which pads are arranged may be disposed on the first end portion of the flexible circuit board 20. The second pad portion PDb may be bonded to the first pad portion PDa.

The pads of the flexible circuit board 20 may be electrically connected to the pads of the display panel 1000. For mechanical and electrical bonding between the first pad portion PDa and the second pad portion PDb, an anisotropic conductive layer (not shown) may be disposed between the first pad portion PDa and the second pad portion PDb. The anisotropic conductive layer may have a form in which conductive particles are spread in a film-type thermosetting resin (e.g., epoxy resin, acryl resin, polyester resin, bismaleimide resin, cyanate resin, etc.). The anisotropic conductive layer may mechanically and electrically bond electronic components by a process for simultaneously applying heat and pressure.

The display panel 1000 may include a plurality of first pad portions PDa, and the first pad portions PDa may be spaced from each other along an edge of the display panel 1000. The second pad portion PDb of the corresponding flexible circuit board 20 may be bonded to corresponding first pad portion PDa. In another embodiment, the display panel 1000 may include one first pad portion PDa depending on sizes, and one flexible circuit board 20 may be bonded.

A driving unit for generating and/or processing various signals for driving the display panel 1000 may be disposed in the non-display area NDA of the display panel 1000. The driving unit may include a data driver for applying a data signal to the data line 171, a gate driver for applying a gate signal to the first scan line 121 and the second scan line 122, and a signal controller for controlling the data driver and the gate driver.

The pixels PX may receive a data voltage or an initializing voltage at predetermined timing according to the scan signal generated by the gate driver. The gate driver may be integrated to the display panel 1000, and may be disposed on at least one side of the display area DA.

The data driver may be provided as an integrated circuit chip 30. The integrated circuit chip 30 may be mounted on the flexible circuit board 20. The signals output by the integrated circuit chip 30 may be transmitted to the display panel 1000 through the second pad portion PDb of the flexible circuit board 20 and the first pad portion PDa of the display panel 1000.

The display device may include a plurality of integrated circuit chips 30, and each of the integrated circuit chips 30 may be disposed on the corresponding flexible circuit board 20. The integrated circuit chip 30 may be mounted in the non-display area NDA of the display panel 1000, and in this case, the integrated circuit chip 30 may be disposed between the display area DA and the first pad portion PDa.

The signal controller may be provided as an integrated circuit chip, and may be mounted on the printed circuit board (PCB) 40. The data driver and the signal controller may be provided as a combined chip.

A pad portion disposed at a second end portion (an opposite end of the first end portion) of the flexible circuit board 20 may be bonded and electrically connected to a pad portion of the printed circuit board (PCB) 40, and signals may be transmitted between the display panel 1000 and the printed circuit board (PCB) 40 through the flexible circuit board 20. The printed circuit board (PCB) 40 may include a plurality of pad portions, and the pad portions may be spaced from each other along one edge of the display panel 1000. The printed circuit board (PCB) 40 may include a plurality of pad portions that corresponds to a plurality of the flexible circuit boards 20.

The integrated circuit chip 30 may output the signals provided to the display area DA. For example, the integrated circuit chip 30 may output a data voltage, a driving voltage, a common voltage, and an initializing voltage. A data voltage transmitting line, a driving voltage transmitting line, a common voltage transmitting line, and an initializing voltage line for transmitting the data voltage, the driving voltage, the common voltage, and the initializing voltage output by the integrated circuit chip 30 to the data line 171, the driving voltage line 172, the common voltage line 173, and the initializing voltage line 174 of the display area DA may be disposed in the non-display area NDA. The integrated circuit chip 30 may also output signals for controlling the gate driver.

The signals output by the integrated circuit chip 30 may be input to the display panel 1000 through the first pads of the first pad portion PDa connected to the second pads of the second pad portion PDb of the flexible circuit board 20.

The integrated circuit chip 30 may receive signals (e.g., image data, signals relating to the image data, and power voltages) that are used to generate the above-described signals through pads of the pad portion disposed on the second end portion of the flexible circuit board 20 connected to pads of the pad portion of the printed circuit board (PCB) 40. A processor and a memory may be disposed on the printed circuit board (PCB) 40. When the display device is applied to a mobile communication terminal, the processor may be an application processor including a central processing device, a graphics signal processing device, and a modem. The flexible circuit board 20 may be bent, and the printed circuit board (PCB) 40 may be disposed on a rear side of the display panel 1000.

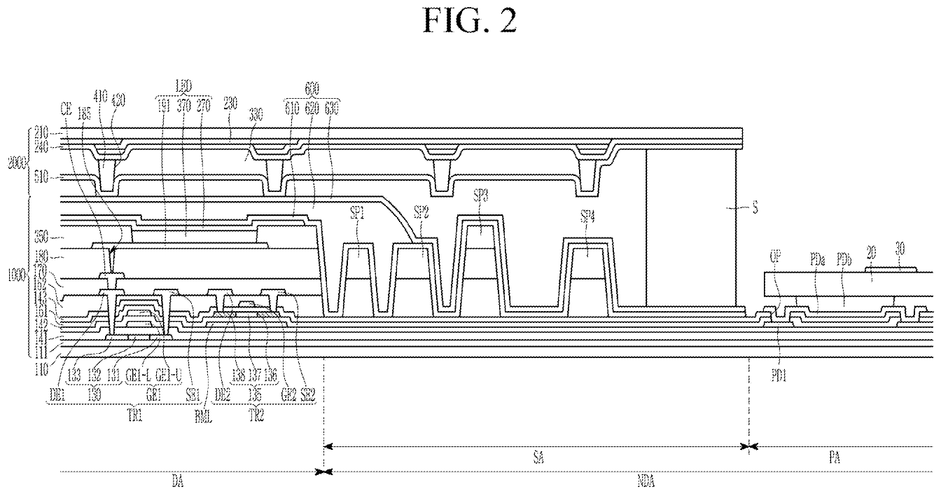

A display device will now be described with reference to FIG. 1 and FIG. 2. FIG. 2 shows a cross-sectional view of a display device according to an embodiment.

Referring to FIG. 1 and FIG. 2, the display device according to an embodiment includes a display area DA in which a plurality of pixels PX are disposed and a non-display area NDA disposed near the display area DA.

The display area DA will now be described.

The display area DA includes a display panel 1000 and a color converting panel 2000. Although not shown, the display device may further include a touch unit, and the touch unit may be disposed between the display panel 1000 and the color converting panel 2000.

The display panel 1000 includes a first substrate 110. The first substrate 110 may include a flexible material, such as plastic, that may be easily bent, folded, or rolled.

Although not shown, the substrate 110 may include a plurality of insulating films overlapping each other, and may further include a barrier film disposed between the overlapping insulating films in a plan view.

A buffer layer 111 is disposed on the first substrate 110.

The buffer layer 111 may be disposed between the first substrate 110 and the semiconductor layer 130 and may block impurities from the first substrate 110 in a crystallization process for forming polysilicon, thereby improving a characteristic of the polysilicon.

The buffer layer 111 may include an inorganic insulating material such as a silicon oxide (SiOₓ), a silicon nitride (SiNₓ), and/or a silicon oxynitride (SiOₓN_{y}). The buffer layer 111 may include amorphous silicon (Si).

A first semiconductor 130 may be disposed on the buffer layer 111. The first semiconductor 130 may include a polycrystalline silicon material. That is, the first semiconductor 130 may be made of a polycrystalline semiconductor. The first semiconductor 130 may include a source region 131, a channel region 132, and a drain region 133.

The source region 131 of the first semiconductor 130 may be connected to a first source electrode SE1, and the drain region 133 of the first semiconductor 130 may be connected to a first drain electrode DE1.

A first gate insulating layer 141 may be disposed on the first semiconductor 130. The first gate insulating layer 141 may have a single- or multi-layered structure including a silicon nitride, a silicon oxide, and/or a silicon oxynitride.

A first gate lower electrode GE1-L may be disposed on the first gate insulating layer 141. The first gate lower electrode GE1-L may include molybdenum (Mo), aluminum (Al), copper (Cu), and/or titanium (Ti), and may have a single- or multi-layered structure including them.

A second gate insulating layer 142 may be disposed on the first gate lower electrode GE1-L. The second gate insulating layer 142 may include a silicon nitride, a silicon oxide, and/or a silicon oxynitride. The second gate insulating layer 142 may have a single- or multi-layered structure including a silicon nitride, a silicon oxide, and/or a silicon oxynitride.

A first gate upper electrode GE1-U may be disposed on the second gate insulating layer 142. The second gate lower electrode GE1-L may overlap the second gate upper electrode GE1-U with the second gate insulating layer 142 therebetween. The first gate upper electrode GE1-U and the first gate lower electrode GE1-L configure a first gate electrode GE1. The first gate electrode GE1 may overlap the channel region 132 of the first semiconductor 130 in a third direction Z that is perpendicular to the first substrate 110.

The first gate upper electrode GE1-U may include molybdenum (Mo), aluminum (Al), copper (Cu), silver (Ag), chromium (Cr), tantalum (Ta), and/or titanium (Ti), and may have a single- or multi-layered structure including them.

A metal layer BML made of the same layer as the first gate upper electrode GE1-U may be disposed on the second gate insulating layer 142, and the metal layer BML may overlap a second transistor TR2 to be described. The metal layer BML may be connected to the driving voltage line or a gate electrode or a source electrode of the second transistor TR2, and may function as a lower gate electrode.

The first semiconductor 130, the first gate electrode GE1, the first source electrode SE1, and the first drain electrode DE1 configure a first transistor TR1. The first transistor TR1 may be a driving transistor connected to the light emitting diode LED, and may be made of a transistor including a polycrystalline semiconductor.

A first interlayer-insulating layer 161 may be disposed on the first gate electrode GE1. The first interlayer-insulating layer 161 may include a silicon nitride, a silicon oxide, and/or a silicon oxynitride. The first interlayer-insulating layer 161 may be made of multiple layers with a stack of a layer including a silicon nitride and a layer including a silicon oxide. In this instance, the layer including a silicon nitride of the first interlayer-insulating layer 161 may be disposed nearer the substrate 110 than the layer including a silicon oxide is.

A second semiconductor 135 may be disposed on the first interlayer-insulating layer 161. The second semiconductor 135 may overlap the metal layer BML in a plan view.

The second semiconductor 135 may include an oxide semiconductor. The oxide semiconductor may include at least one of an indium (In) oxide, a tin (Sn) oxide, a zinc (Zn) oxide, a hafnium (Hf) oxide, and/or an aluminum (Al) oxide. For example, the second semiconductor 135 may include an indium-gallium-zinc oxide (“IGZO”).

The second semiconductor 135 may include a channel region 137, and a source region 136 and a drain region 138 disposed on opposite sides of the channel region 137. The source region 136 of the second semiconductor 135 may be connected to the second source electrode SE2, and the drain region 138 of the second semiconductor 135 may be connected to the second drain electrode DE2.

A third gate insulating layer 143 may be disposed on the second semiconductor 135. The third gate insulating layer 143 may include a silicon nitride, a silicon oxide, and/or a silicon oxynitride.

In the shown embodiment, the third gate insulating layer 143 may be disposed on front sides (i.e., upper sides) of the second semiconductor 135 and the first interlayer-insulating layer 161. Therefore, the third gate insulating layer 143 covers upper sides and lateral sides of the source region 136, the channel region 137, and the drain region 138 of the second semiconductor 135.

When the third gate insulating layer 143 does not cover the upper sides of the source region 136 and the drain region 138, a portion of a material of the second semiconductor 135 may move to a lateral side of the third gate insulating layer 143. In the present embodiment, as the third gate insulating layer 143 is disposed on the front sides of the second semiconductor 135 and the first interlayer-insulating layer 161, a short-circuit of the second semiconductor 135 and the second gate electrode GE2 caused by a diffusion of metal particles may be prevented.

The embodiments are not limited thereto, and the third gate insulating layer 143 may not be disposed on the front sides of the second semiconductor 135 and the first interlayer-insulating layer 161. In another embodiment, for example, the third gate insulating layer 143 may be disposed between the second gate electrode GE2 and the second semiconductor 135. That is, the third gate insulating layer 143 may overlap the channel region 137 of the second semiconductor 135, and may not overlap the source region 136 and the drain region 138 in a plan view. Hence, a length of the channel of the semiconductor 135 may be reduced in a high-resolution realizing process.

A second gate electrode GE2 may be disposed on the third gate insulating layer 143.

The second gate electrode GE2 may overlap the channel region 137 of the second semiconductor 135 in the third direction Z that is perpendicular to the substrate 110. The second gate electrode GE2 may include molybdenum (Mo), aluminum (Al), copper (Cu), and/or titanium (Ti), and may have a single- or multi-layered structure including them. For example, the second gate electrode GE2 may include a lower layer including titanium and an upper layer including molybdenum, and the lower layer including titanium may prevent diffusion of fluorine (F) that is etching gas when the upper layer is dry-etched.

The second semiconductor 135, the second gate electrode GE2, the second source electrode SE2, and the second drain electrode DE2 configure a second transistor TR2. The second transistor TR2 may be a switching transistor for switching the first transistor TR1, and may be made of a transistor including an oxide semiconductor.

A second interlayer-insulating layer 162 may be disposed on the second gate electrode GE2. The second interlayer-insulating layer 162 may include a silicon nitride, a silicon oxide, and/or a silicon oxynitride. The second interlayer-insulating layer 162 may be a multilayer that is a stack of a layer including a silicon nitride and a layer including a silicon oxide.

A first source electrode SE1, a first drain electrode DE1, a second source electrode SE2, and a second drain electrode DE2 may be disposed on the second interlayer-insulating layer 162. The first source electrode SE1, the first drain electrode DE1, the second source electrode SE2, and the second drain electrode DE2 may include aluminum (Al), molybdenum (Mo), titanium (Ti), tungsten (W), and/or copper (Cu), and may have a single- or multi-layered structure. For example, the first source electrode SE1, the first drain electrode DE1, the second source electrode SE2, and the second drain electrode DE2 may have a triple-layered structure including a lower layer including a refractory metal, such as titanium, molybdenum, chromium, or tantalum, or an alloy thereof, an intermediate layer including an aluminum-based metal with low resistivity, a silver-based metal, and/or a copper-based metal, and an upper layer including a refractory metal such as titanium, molybdenum, chromium, or tantalum.

The first source electrode SE1 may be connected to the source region 131 of the first semiconductor 130, and the first drain electrode DE1 may be connected to the drain region 133 of the first semiconductor 130.

The second source electrode SE2 may be connected to the source region 136 of the second semiconductor 135, and the second drain electrode DE2 may be connected to the drain region 138 of the second semiconductor 135.

A first insulating layer 170 may be disposed on the first source electrode SE1, the first drain electrode DE1, the second source electrode SE2, and the second drain electrode DE2. The first insulating layer 170 may be an organic film or an inorganic film. For example, the first insulating layer 170 may include an organic insulating material including a general-purpose polymer such as polymethyl methacrylate or polystyrene, a polymer derivative having a phenol-based group, an acryl-based polymer, an imide-based polymer, a polyimide, and/or a siloxane-based polymer.

A connection electrode CE, a data line 171, and a driving voltage line 172 may be disposed on the first insulating layer 170. The connection electrode CE and the data line DL may include aluminum (Al), silver (Ag), magnesium (Mg), gold (Au), nickel (Ni), chromium (Cr), calcium (Ca), molybdenum (Mo), titanium (Ti), tungsten (W), and/or copper (Cu), and may have a single- or multi-layered structure including at least one of them.

The connection electrode CE is connected to the first drain electrode DE1.

A second insulating layer 180 may be disposed on the first insulating layer 170, the connection electrode CE, and the data line DL. The second insulating layer 180 may eliminate steps and perform planarization to increase light emitting efficiency of the emission layer to be formed thereon. The second insulating layer 180 may include an organic insulating material including a general-purpose polymer such as polymethyl methacrylate or polystyrene, a polymer derivative having a phenol-based group, an acryl-based polymer, an imide-based polymer, a polyimide, and/or a siloxane-based polymer.

A pixel electrode 191 may be disposed on the second insulating layer 180. The pixel electrode 191 may be connected to the first drain electrode DE1 through a contact hole of the second insulating layer 180.

The pixel electrode 191 may be individually disposed on each of the pixels PX. The pixel electrode 191 may include a metal such as silver (Ag), lithium (Li), calcium (Ca), aluminum (Al), magnesium (Mg), or gold (Au), and may include a transparent conductive oxide (“TCO”) such as an indium tin oxide (“ITO”) or an indium zinc oxide (“IZO”). The pixel electrode 191 may be made of a single layer including a metal material or a transparent conductive oxide or a multilayer including them. For example, the pixel electrode 191 may have a triple-layered structure of indium tin oxide (ITO)/silver (Ag)/indium tin oxide (ITO).

A pixel defining film 350 may be disposed on the pixel electrode 191. The pixel defining film 350 may include an organic insulating material including a general-purpose polymer such as polymethyl methacrylate or polystyrene, a polymer derivative having a phenol-based group, an acryl-based polymer, an imide-based polymer, a polyimide, and/or a siloxane-based polymer. The pixel defining film 350 may include a black dye and may not transmit light.

The pixel defining film 350 may define a pixel opening overlapping the pixel electrode 191 in a plan view, and an emission layer 370 may be disposed in the pixel opening of the pixel defining film 350.

The emission layer 370 may include a material layer for uniquely displaying primary colors such as red, green, and blue. The emission layer 370 may have a structure in which a plurality of material layers for displaying light of different colors are stacked.

For example, the emission layer 370 may be an organic emission layer, and the organic emission layer may be a multilayer including at least one of an emission layer, a hole injection layer (“HIL”), a hole transporting layer (“HTL”), an electron transporting layer (“ETL”), and an electron injection layer (“EIL”). When the organic emission layer includes all of the layers, the hole injection layer may be disposed on the pixel electrode 191 that is an anode, and the hole transporting layer, the emission layer, the electron transporting layer, and the electron injection layer may be sequentially stacked thereon.

A common electrode 270 may be disposed on the emission layer 370 and the pixel defining film 350. The common electrode 270 may be disposed in common on all pixels PX, and may receive a common voltage through a common voltage transmitter (not shown) of the non-display area NDA.

The common electrode 270 may include a reflective metal such as calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), or lithium (Li), or a transparent conductive oxide (TCO) such as an indium tin oxide (ITO) or an indium zinc oxide (IZO).

The pixel electrode 191, the emission layer 370, and the common electrode 270 may configure a light emitting diode LED. The pixel electrode 191 may be an anode that is the hole injection electrode, and the common electrode 270 may be a cathode that is the electron injection electrode. However, the embodiment is not limited thereto. In another embodiment, the pixel electrode 191 may be a cathode and the common electrode 270 may be an anode depending on the method for driving an organic light emitting device.

Light emits when holes and electrons are injected into the emission layer 370 from the pixel electrode 191 and the common electrode 270, and excitons that are a combination of the injected holes and the electrons fall to the ground state from the excited state.

The first transistor TR1 that is a driving transistor of the display device according to an embodiment may include a polycrystalline semiconductor, and the second transistor TR2 that is part of the switching transistor may include an oxide semiconductor. A motion of a video may be further naturally expressed by increasing an existing frequency of about 60 hertz (Hz) to about 120 Hz for the purpose of high-rate driving, but power consumption is increased by this. To compensate for the increased power consumption, the frequency for driving a still image may be lowered. For example, the still image may be driven with the frequency of about 1 Hz. When the frequency is lowered as described above, a leakage current may be generated. According to the display device according to an embodiment, the first transistor TR1 that is a driving transistor is allowed to include a polycrystalline semiconductor so that it may have high electron mobility, and the second transistor TR2 that is a switching transistor is allowed to include an oxide semiconductor so that the leakage current may be minimized. That is, when the switching transistor and the driving transistor are allowed to include different semiconductor materials, they may be stably driven and may have high reliability.

An encapsulation layer 600 (in other words, thin film encapsulation layer) is disposed on the common electrode 270. The encapsulation layer 600 may cover the upper side and the lateral side of the display panel 1000 to seal the display panel 1000.

The encapsulation layer 600 may include a plurality of layers, and may be made of a complex layer including an inorganic film and an organic film from among the layers. For example, the encapsulation layer 600 may be made of triple layers with a sequential formation of a first inorganic encapsulation layer 610, an organic encapsulation layer 620, and a second inorganic encapsulation layer 630.

A color converting panel 2000 is disposed on the encapsulation layer 600.

The color converting panel 2000 includes a second substrate 210 facing the first substrate 110 of the display panel 1000. The second substrate 210 may include a flexible material, such as plastic, that may be easily bent, warped, folded, or rolled.

A plurality of color filters 230, a fourth insulating layer 240, a partition wall 410, a plurality of color converting layers 330, and a third insulating layer 510 are disposed between the second substrate 210 and the display panel 1000.

Regarding the color converting panel 2000, without an additional light blocking member, an overlapping region in which the color filters 230 for transmitting different colors may provide a light blocking region (not shown).

A filling layer (not shown) may be disposed between the third insulating layer 510 and the display panel 1000.

The partition wall 410 overlaps the pixel defining film 350 of the display panel 1000. That is, the partition wall 410 overlaps an opaque region of the display panel 1000, and the color converting layers 330 overlap a light emitting region of the display panel 1000 in a plan view.

The partition wall 410 overlaps a light blocking region of the color converting panel 2000.

The partition wall 410 may define openings 420 overlapping the color filters 230 in a plan view, the color converting layers 330 may be disposed in the openings 420 of the partition wall 410, and the color converting layers 330 may be disposed in a region surrounded by the partition wall 410.

The color converting layers 330 may include a transmission layer (not shown) transmitting light with a first wavelength that is input from the display panel and including a plurality of scatterers (not shown), a first color converting layer color-converting the light with a first wavelength input from the display panel into light with a second wavelength and including a plurality of first quantum dots and a plurality of scatterers, and a second color converting layer color-converting the light with a first wavelength input from the display panel into light with a third wavelength and including a plurality of second quantum dots and a plurality of scatterers. The light with a first wavelength may be blue light with a maximally emitted peak wavelength of about 380 nm to about 480 nm, for example, equal to or greater than about 420 nm, equal to or greater than about 430 nm, equal to or greater than about 440 nm, or equal to or greater than about 445 nm, and equal to or less than about 470 nm, equal to or less than about 460 nm, or equal to or less than about 455 nm. The light with a second wavelength may be red light with the maximally emitted peak wavelength of about 600 nm to about 650 nm, for example, about 620 nm to about 650 nm, and the light with a third wavelength may be green light with the maximally emitted peak wavelength of about 500 nm to about 550 nm, for example, about 510 nm to about 550 nm.

The color filters 230 may include a first color filter for transmitting the light with a second wavelength, and absorbing the light with other wavelengths to increase purity of the light with a second wavelength color-converted after passing through the first color converting layer and emitted toward the second substrate 210, a second color filter for transmitting the light with a third wavelength, and absorbing the light with other wavelengths to increase purity of the light with a third wavelength color-converted after passing through the second color converting layer and emitted toward the second substrate 210, and a third color filter for transmitting the light with a first wavelength having passed through the transmission layer and absorbing the light with other wavelengths to increase purity of the light with a first wavelength having passed through the transmission layer and emitted toward the second substrate 210.

The scatterers may scatter the light input to the color converting layers 330 to increase efficiency of light.

The third insulating layer 510 covers and protects the color converting layers 330 to prevent a component of a filling layer injected when the color converting panel 2000 is attached to the display panel from being input to the color converting layers 330.

The non-display area NDA will now be described.

The non-display area NDA includes a blocking area SA and a driver area PA.

A first spacer SP1, a second spacer SP2, a third spacer SP3, and a fourth spacer SP4 are disposed in the blocking area SA of the non-display area NDA. The first spacer SP1, the second spacer SP2, the third spacer SP3, and the fourth spacer SP4 are disposed to be distant in order from the display area DA. That is, the second spacer SP2 is disposed on a more external portion than the first spacer SP1 is, the third spacer SP3 is disposed on a more external portion than the second spacer SP2 is, and the fourth spacer SP4 is disposed on a more external portion than the third spacer SP3 is.

The first spacer SP1 and the second spacer SP2 may be made on the same layer as the first insulating layer 170 and the second insulating layer 180 disposed in the display area DA, and the third spacer SP3 may be configured with an insulating layer made on the same layer as the first insulating layer 170, the second insulating layer 180, and the pixel defining film 350 disposed in the display area DA and an additional insulating layer. The fourth spacer SP4 may be made on the same layer as the first insulating layer 170 and the second insulating layer 180 disposed in the display area DA, and is not limited thereto.

The first inorganic encapsulation layer 610 and the second inorganic encapsulation layer 630 are formed on the front side of the substrate 110 and are disposed on the first spacer SP1, the second spacer SP2, the third spacer SP4, and the fourth spacer SP4. The organic encapsulation layer 620 is not disposed in external area of the second spacer SP2 from among the non-display area NDA. Therefore, the organic encapsulation layer 620 is not disposed in the driver area PA.

When the organic encapsulation layer 620 is formed, the first spacer SP1, the second spacer SP2, the third spacer SP3, and the fourth spacer SP4 may function as dams for preventing an organic material from overflowing, and the organic material is formed to not overflow to external areas of the first spacer SP1 to the fourth spacer SP4, so the organic encapsulation layer 620 may be formed to not be disposed in the external areas of the first spacer SP1 to the fourth spacer SP4.

A sealant S disposed between the first substrate 110 and the second substrate 210 and combining and sealing the first substrate 110 and the second substrate 210 is disposed in the blocking area SA of the non-display area NDA.

The color filter 230 and the color converting layer 330 may be disposed on a portion of the second substrate 210 overlapping the sealant S from among the second substrate 210.

When the sealant S is formed, the fourth spacer SP4 may prevent the sealant S from being diffused toward the display area DA.

The second substrate 210 of the color converting panel 2000 is disposed in the display area DA and the blocking area SA of the non-display area NDA and is not disposed in the driver area PA of the non-display area NDA.

A signal pad portion PD1 connected to signal lines of the display area DA, a first pad portion PDa connected to the signal pad portion PD1, and a second pad portion PDb of the flexible circuit board 20 are disposed in the driver area PA of the non-display area NDA.

The signal pad portion PD1 may be formed on the same layer as the metal layer BML of the display area DA, and the first pad portion PDa may be formed on the same layer as the first source electrode SE1 and the first drain electrode DE1, and the second source electrode SE2 and the second drain electrode DE2.

The signal pad portion PD1 is connected to the first pad portion PDa through a contact hole OP defined in the second gate insulating layer 142 and the first interlayer-insulating layer 161 disposed thereon.

The first inorganic encapsulation layer 610 and the second inorganic encapsulation layer 630 of the encapsulation layer 600 may be removed from the driver area PA of the non-display area NDA, and the first pad portion PDa that is not covered by the first inorganic encapsulation layer 610 and the second inorganic encapsulation layer 630 may be connected to the second pad portion PDb formed on the flexible circuit board 20.

Signals output by the integrated circuit chip 30 mounted on the flexible circuit board 20 may be transmitted to the display panel 1000 through the second pad portion PDb of the flexible circuit board 20 and the first pad portion PDa of the display panel 1000.

A method for manufacturing a display device according to an embodiment will now be described with reference to FIG. 1 through FIG. 5

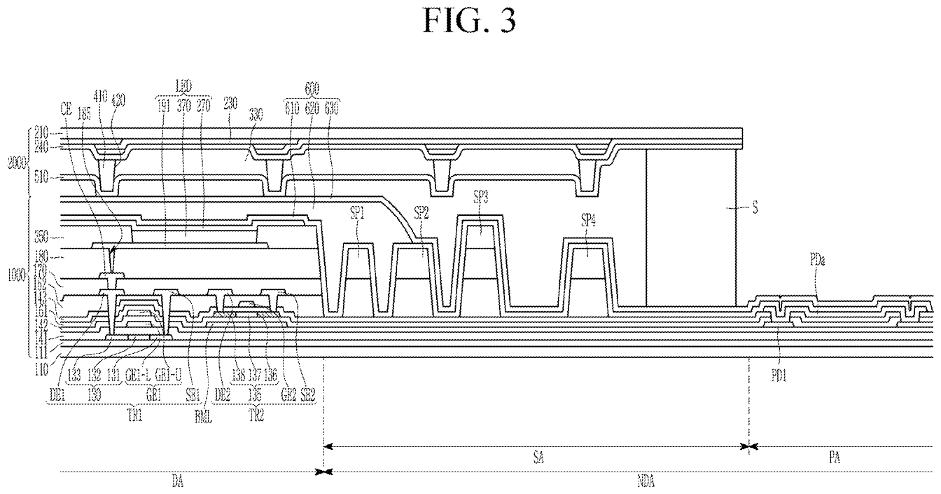

FIG. 3 to FIG. 5 show cross-sectional views of a method for manufacturing a display device according to an embodiment.

The method for manufacturing a display device will focus on a process for bonding a flexible circuit board 20 to a display panel 1000 (referred to as an outer lead bonding (“OLB”) process).

Referring to FIG. 1, FIG. 2, and FIG. 3, a display area DA including a display panel 1000 and a color converting panel 2000, and a non-display area NDA including a blocking area SA in which a first spacer SP1 to a fourth spacer SP4 are disposed and a driver area PA in which a signal pad portion PD1 and a first pad portion PDa connected to the signal pad portion PD1 are disposed are formed.

A first inorganic encapsulation layer 610 and a second inorganic encapsulation layer 630 are formed on the front side of the substrate 110 and are disposed in the blocking area SA of the non-display area NDA and the driver area PA.

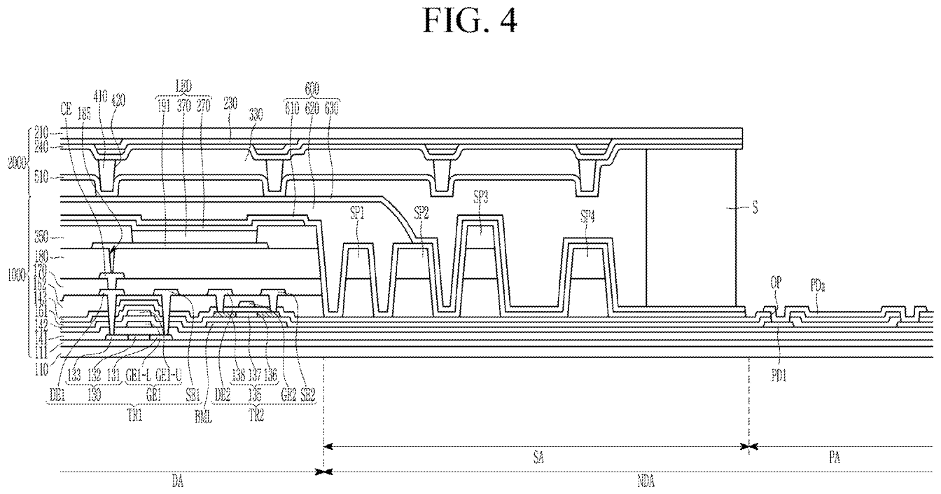

Referring to FIG. 1, FIG. 2, and FIG. 4, the first pad portion PDa is exposed by removing the first inorganic encapsulation layer 610 and the second inorganic encapsulation layer 630 disposed in the driver area PA of the non-display area NDA. The first inorganic encapsulation layer 610 and the second inorganic encapsulation layer 630 in the driver area PA are removed by plasma etching using the plasma processing device.

When the first inorganic encapsulation layer 610 and the second inorganic encapsulation layer 630 are removed by the plasma etching, plasma etch gas may not be fluently supplied to the region that is near the blocking area SA from among the driver area PA of the non-display area NDA by a step that is a surface height difference between the display area DA and the blocking area SA including the display panel 1000 and the color converting panel 2000 and the driver area PA of the non-display area NDA in which the color converting panel 2000 is not disposed, and hence, the first inorganic encapsulation layer 610 and the second inorganic encapsulation layer 630 may not be well removed in the region that is near the display area DA from among the driver area PA of the non-display area NDA. When the first inorganic encapsulation layer 610 and the second inorganic encapsulation layer 630 are not well removed as described above, the first pad portion PDa of the driver area PA may not be completely exposed, and the first pad portion PDa may not easily contact the second pad portion PDb.

According to the method for manufacturing a display device according to the present embodiment, by removing the first inorganic encapsulation layer 610 and the second inorganic encapsulation layer 630 of the driver area PA by use of a plasma processing device 900, the plasma etch gas may be uniformly supplied to the region that is near the display area DA from among the driver area PA of the non-display area NDA, and the first inorganic encapsulation layer 610 and the second inorganic encapsulation layer 630 in the driver area PA may be easily removed even if there is the step that is a surface height difference between the blocking area SA and the driver area PA. This will be described in detail in a later portion of the present specification.

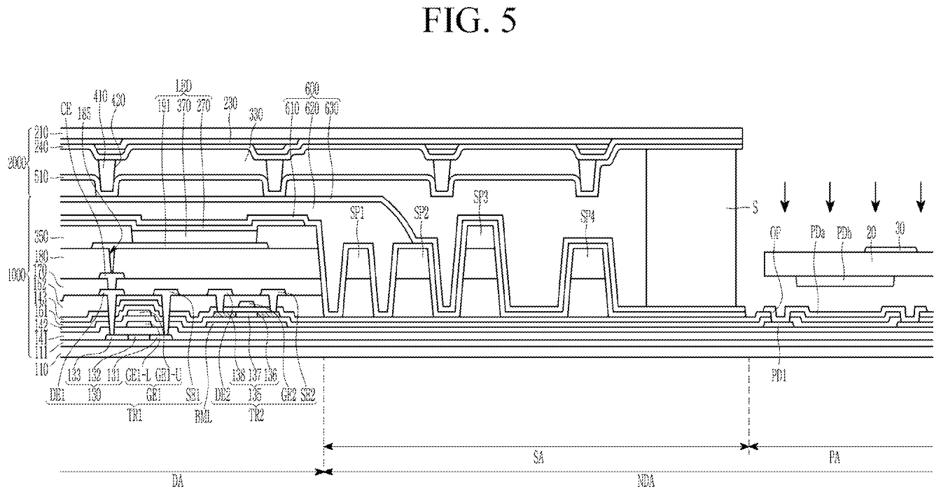

Referring to FIG. 1, FIG. 2, and FIG. 5, the integrated circuit chip 30 is mounted in the driver area PA of the non-display area NDA in which the first inorganic encapsulation layer 610 and the second inorganic encapsulation layer 630 are removed and the first pad portion PDa is exposed, and the flexible circuit board 20 on which the second pad portion PDb is disposed is disposed and compressed to bond and connect the second pad portion PDb of the flexible circuit board 20 and the first pad portion PDa of the display panel 1000.

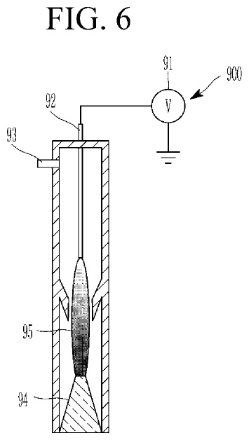

A plasma processing device 900 used in the method for manufacturing a display device according to the present embodiment will now be described with reference to FIG. 6. FIG. 6 shows a schematic diagram of a plasma processing device according to an embodiment.

Referring to FIG. 6, the plasma processing device 900 according to the present embodiment includes a power supply unit 91, a plasma processor 90 including a plasma electrode 92 connected to the power supply unit 91, a gas supply unit 93 for supplying process gas to the plasma processor 90, a process gas discharging duct 94 for discharging plasma-processed process gas, and a gas direction changer 95 disposed between the plasma processor 90 and the process gas discharging duct 94.

The gas direction changer 95 supplies uniform process gas when there is a big step on a portion processed by changing the direction in which the process gas plasma-processed by the plasma processor 90 is supplied.

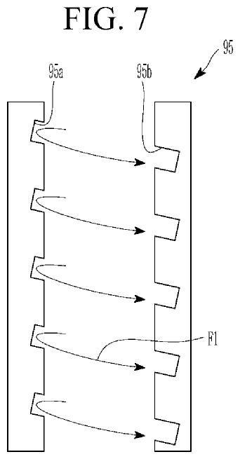

A gas direction changer 95 of a plasma processing device 900 according to an embodiment will now be described with reference to FIG. 6 and FIG. 7. FIG. 7 shows a cross-sectional view of a gas direction changer of a plasma processing device according to an embodiment.

Referring to FIG. 6 and FIG. 7, the gas direction changer 95 of the plasma processing device 900 according to the present embodiment has a nozzle shape including groove portions 95a and 95b defined therein. The groove portions 95a and 95b of the gas direction changer 95 may be connected to each other, and the groove portions 95a and 95b of the gas direction changer 95 may be grooves connected in a spiral shape in the gas direction changer 95.

The groove portions 95a and 95b may be inclined to form a predetermined angle with respect to an inner surface of the gas direction changer 95. For example, the groove portions 95a and 95b may be inclined with an angle of about 30 degrees to about 60 degrees with respect to a normal direction of the inner surface (i.e., inner side) of the gas direction changer 95, and in detail, it may be inclined with the angle of about 30 degrees, about 45 degrees, or about 60 degrees. The groove portions 95a and 95b may be spiral grooves with equal intervals.

Depths of the groove portions 95a and 95b may be about 1 millimeter (mm) to about 2 mm.

When the groove portions 95a and 95b are inclined from the surface of the gas direction changer 95 with the angle of about 45 degrees, an interval of the groove portions 95a and 95b may be about 10 mm, in detail, about 10.205 mm.

The process gas plasma-processed by the plasma processor 90 of the plasma processing device 900 may pass through the gas direction changer 95, may pass through the groove portions 95a and 95b of the gas direction changer 95, may receive a force so that it may be rotated in a first direction Fl, and may be discharged in a turbulent flow form to the process gas discharging duct 94.

As described above, since the process gas passes through the groove portions 95a and 95b of the gas direction changer 95, receives a force to be rotated in the first direction FL and is discharged in a turbulent flow form to the process gas discharging duct 94, even when there is a step that is the surface height difference of the processor 90, plasma etching gas may be uniformly supplied to the region that is near the step portion.

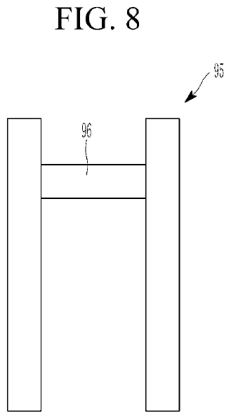

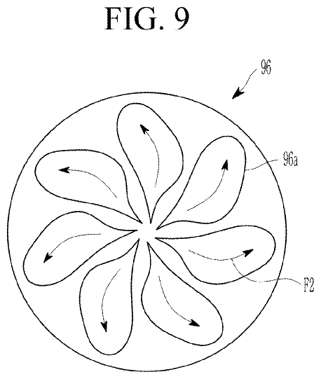

A gas direction changer 95 of a plasma processing device 900 according to an embodiment will now be described with reference to FIG. 6, FIG. 8, and FIG. 9. FIG. 8 shows a cross-sectional view of a gas direction changer of a plasma processing device according to an embodiment, and FIG. 9 shows a top plan view of a gas direction changing filter of a plasma processing device according to an embodiment.

Referring to FIG. 8, the gas direction changer 95 of the plasma processing device 900 according to the present embodiment has a nozzle shape including a gas direction changing filter 96 disposed therein.

The gas direction changing filter 96 of the gas direction changer 95 may be disposed to traverse an inside of the gas direction changer 95. That is, the gas direction changing filter 96 may be disposed to traverse the nozzle shape of the gas direction changer 95.

Referring to FIG. 9, the gas direction changing filter 96 of the gas direction changer 95 defines a plurality of grooves 96a therein, the process gas passes through the grooves 96a and receives a force to be rotated in a second direction F2, and is discharged in a turbulent flow form to the process gas discharging duct 94. Therefore, even when there is a step that is the surface height difference of the processor 90, the plasma etching gas may be uniformly supplied to the region that is near the step portion.

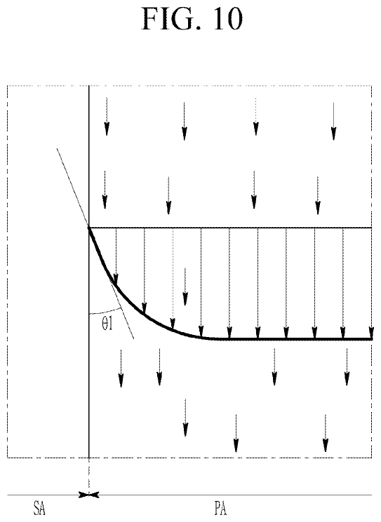

An operation of the gas direction changer 95 of the plasma processing device 900 according to the present embodiment will now be described with reference to FIG. 10 through FIG. 13.

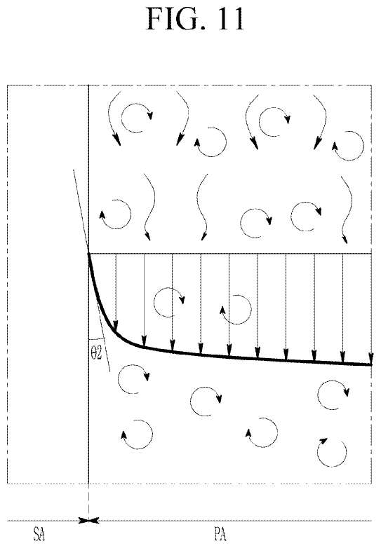

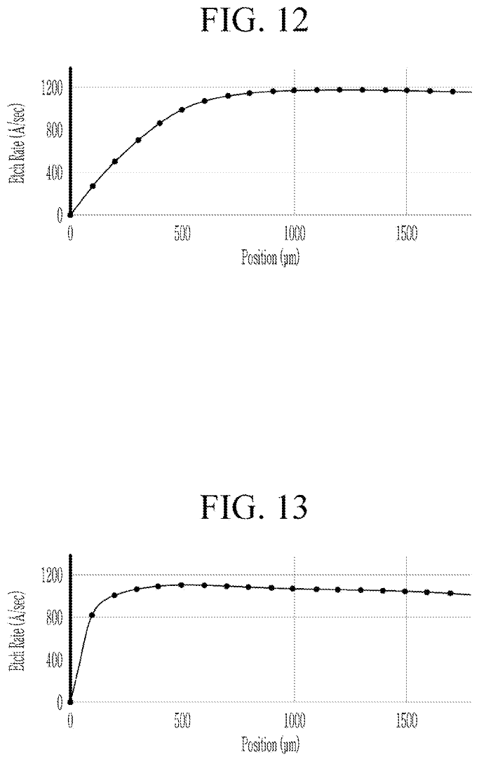

FIG. 10 and FIG. 11 show graphs of a supplying direction and a supplied amount of gas supplied to a step portion, and FIG. 12 and FIG. 13 show graphs of etch rates with respect to position.

FIG. 10 and FIG. 12 show a case that a plasma processing device does not include a gas direction changer 95, and FIG. 11 and FIG. 13 show a case that a plasma processing device includes a gas direction changer in a like way of the plasma processing device according to an embodiment.

Referring to FIG. 10, when the plasma processing device does not include the gas direction changer 95, the process gas discharged to the process gas discharging duct 94 is discharged in a linear flow form, and is then supplied toward the substrate 110 from top to bottom as shown in FIG. 10.

As there is a step that is the surface height difference between the blocking area SA and the driver area PA, it is difficult to supply sufficient process gas to an adjacent portion of the blocking area SA and the driver area PA because of an influence by the height of the blocking area SA.

In detail, a flux of the process gas supplied to the substrate 110 from the plasma processing device 900 is reduced to have a slope with a first angle 01 at the portion of the driver area PA adjacent to the blocking area SA, and the process gas flux is gradually increased in a direction toward the driver area PA from the blocking area SA.

Referring to FIG. 11, in a similar way of the plasma processing device 900 according to an embodiment, when the plasma processing device 900 includes the gas direction changer 95, the process gas discharged to the process gas discharging duct 94 passes through the gas direction changer 95 and is changed into a turbulent flow form, and is then, as shown in FIG. 11, supplied toward substrate 110 in a turbulent flow form.

When there is a step that is the surface height difference between the blocking area SA and the driver area PA, the process gas supplied in the turbulent flow form may be sufficiently supplied to the portion of the driver area PA adjacent to the blocking area SA, and much more process gas than the process gas in the case shown with reference to FIG. 10 may be supplied to the portion adjacent to the blocking area SA.

Therefore, as shown in FIG. 11, in order for the process gas supplied to the substrate 110 from the plasma processing device 900 to have a slope with the second angle θ2, the flux of the process gas may not be reduced at the portion to the blocking area SA, and the process gas flux may be substantially constant in a direction toward the driver area PA from the blocking area SA. The second angle θ2 is less than the first angle θ1.

Referring to FIG. 12, when the plasma processing device includes no gas direction changer 95, the process gas discharged to the process gas discharging duct 94 is linearly discharged, so regarding an etch rate using the process gas, the etch rate is relatively low on a boundary between the driver area PA and the blocking area SA, the etch rate increases when distant from the blocking area SA, and the etch rate is substantially constant starting from a position that is spaced from the blocking area SA by at least about 700 micrometers (μm) or more.

Referring to FIG. 13, in a similar way of the plasma processing device 900 according to an embodiment, when the plasma processing device 900 includes a gas direction changer 95, the process gas discharged to the process gas discharging duct 94 passes through the gas direction changer 95, is changed into the turbulent flow form, and is discharged, so the etch rate using process gas is not relatively lowered at the position that is near the boundary between the driver area PA and the blocking area SA, and substantially becomes constant starting from the position spaced from the display area DA by more than about 100 μm.

As described with reference to FIG. 10 through FIG. 13, by removing the first inorganic encapsulation layer 610 and the second inorganic encapsulation layer 630 of the driver area PA of the non-display area NDA by using the plasma processing device 900 according to an embodiment, the plasma etching gas may be uniformly supplied to the region that is near the display area DA from among the driver area PA of the non-display area NDA, and the first inorganic encapsulation layer 610 and the second inorganic encapsulation layer 630 in the driver area PA may be removed even if there is a step that is the surface height difference between the blocking area SA and the driver area PA.

Hence, the first inorganic encapsulation layer 610 and the second inorganic encapsulation layer 630 disposed in the driver area PA of the non-display area NDA may be completely removed, and the first pad portion PDa in the boundary portion of the driver area PA may be exposed so that the first pad portion PDa may contact the second pad portion PDb.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

### DESCRIPTION OF SYMBOLS

1000: display panel

2000: color converting panel

110, 210: substrate

DA: display area

NDA: non-display area

SA: blocking area

PA: driver area

PDa, PDb: pad

SP1, SP2: spacer

20: flexible circuit board

30: IC chip

40: printed circuit board (PCB)

900: plasma processing device

91: power supply unit

92: plasma electrode

93: gas supply unit

94: process gas discharging duct

95: gas direction changer

95a, 95b: groove

96: direction changing filter

What is claimed is:

1. A plasma processing device comprising:
a power supply unit;
a plasma electrode connected to the power supply unit;
a plasma processor in which the plasma electrode is installed;
a process gas discharging duct connected to the plasma processor; and
a gas direction changer disposed between the plasma processor and the process gas discharging duct.

2. The plasma processing device of claim 1, wherein
the gas direction changer includes a groove portion defined on an inner side thereof, and
the groove portion has a spiral shape on the inner side of the gas direction changer.

3. The plasma processing device of claim 2, wherein
the groove portion has a predetermined angle with respect to the inner side of the gas direction changer.

4. The plasma processing device of claim 3, wherein
the predetermined angle is about 30 degrees to about 60 degrees.

5. The plasma processing device of claim 3, wherein
a depth of the groove is about 1 millimeter (mm) to about 2 mm.

6. The plasma processing device of claim 3, wherein
the spiral shape of the groove is disposed at an equal interval,
the predetermined angle is about 45 degrees, and
the equal interval is about 10 mm.

7. The plasma processing device of claim 1, wherein
the gas direction changer includes a nozzle and a gas direction changing filter disposed to traverse an inside of the nozzle.

8. The plasma processing device of claim 7, wherein
the gas direction changing filter defines a plurality of holes therein.

9. The plasma processing device of claim 1, wherein
process gas is discharged as a linear flow when passing through the plasma processor, and
the process gas is discharged as a turbulent flow when passing through the gas direction changer.

10. A method for manufacturing a display device comprising:
forming a display panel including a first substrate, a second substrate facing the first substrate, an emission layer disposed between the first substrate and the second substrate, a pad portion disposed on the first substrate, and a thin film encapsulation layer disposed on the pad portion;
removing the thin film encapsulation layer disposed on the pad portion by using a plasma processing device; and
attaching a flexible circuit board on which an integrated circuit chip is mounted to the pad portion exposed by removing the thin film encapsulation layer.

11. The method of claim 10, wherein
the display device further includes a color converting panel disposed between the emission layer and the second substrate,
the display panel includes a display area including the emission layer and the color converting panel, a driver area in which the pad portion is disposed, and a blocking area disposed between the display area and the driver area,
the thin film encapsulation layer includes a first inorganic encapsulation layer, a second inorganic encapsulation layer, and an organic encapsulation layer disposed between the second inorganic encapsulation layer and the second inorganic encapsulation layer,
the organic encapsulation layer is disposed in the display area, the first inorganic encapsulation layer and the second inorganic encapsulation layer are disposed in the display area and the blocking area, and
the removing of the thin film encapsulation layer includes removing the first inorganic encapsulation layer and the second inorganic encapsulation layer disposed in the driver area.

12. The method of claim 10, wherein
the removing of the thin film encapsulation layer includes using process gas discharged as a turbulent flow from the plasma processing device.

13. The method of claim 12, wherein
the plasma processing device includes a power supply unit, a plasma electrode connected to the power supply unit, a plasma processor in which the plasma electrode is installed, a process gas discharging duct connected to the plasma processor, and a gas direction changer disposed between the plasma processor and the process gas discharging duct, and
the removing of the thin film encapsulation layer includes using the process gas passing through the gas direction changer.

14. The method of claim 13, wherein
the gas direction changer includes a groove portion defined on an inside thereof,
the groove portion has a spiral shape on the inside of the gas direction changer, and
the removing of the thin film encapsulation layer includes using the process gas having passing the groove portion of the spiral shape.

15. The method of claim 13, wherein
the gas direction changer includes a nozzle and a gas direction changing filter disposed to traverse an inside of the nozzle, and
the removing of the thin film encapsulation layer includes using the process gas passing through the gas direction changing filter.

16. The method of claim 13, wherein
the gas direction changing filter defines a plurality of holes therein, and
the removing of the thin film encapsulation layer includes using the process gas passing through the holes.

17. The method of claim 13, wherein
the process gas is discharged as a linear flow when passing through the plasma processor, and
the process gas is discharged as a turbulent flow when passing through the gas direction changer.

18. The method of claim 11, wherein
the removing of the first inorganic encapsulation layer and the second inorganic encapsulation layer disposed in the driver area includes using process gas discharged as a turbulent flow from the plasma processing device.

19. The method of claim 18, wherein
a flux of the process gas supplied to a region that is near the display area from among the driver area is substantially equivalent to a flux of the process gas supplied to another region of the driver area.

20. The method of claim 19, wherein
an etch rate of removing of the thin film encapsulation layer spaced apart from the blocking area by about 100 micrometers (μm) from among the driver area is substantially equivalent to the etch rate of removing of the thin film encapsulation layer spaced apart from the blocking area by equal to or greater than about 500 μm from among the driver area.
